(19) United States
(12) Patent Application Publication
(10) Pub. No.: US 2007/0077365 A1
(43) Pub. Date: Apr. 5, 2007

(54) THIN-FILM FORMING METHOD, MAGNETIC RECORDING MEDIUM MANUFACTURING METHOD, AND THIN-FILM FORMING APPARATUS

(75) Inventors: Masao NAKAYAMA, Tokyo (JP); Shigeharu WATASE, Tokyo (JP); Hiromichi KANAZAWA, Tokyo (JP); Takahiro HAYASHI, Tokyo (JP)

Correspondence Address: GREENBLUM & BERNSTEIN, P.L.C., 1950 ROLAND CLARKE PLACE, RESTON, VA, 20191, US

(73) Assignee: TDK CORPORATION, Tokyo (JP)

(21) Appl. No.: 11/533,559

(22) Filed: Sep. 20, 2006

(30) Foreign Application Priority Data
Oct. 4, 2005 (JP) 2005/291163

(51) Int. Cl. G11B 5/84; C08J 7/06; B29C 71/04; C23C 16/48; C23C 16/00

(52) U.S. Cl. 427/497; 427/509; 427/532; 118/718; 427/582; 118/724; 118/722; 118/730

(57) ABSTRACT

A thin-film forming method feeds out a belt-shaped web from a roll produced by winding the web and causes the web to run around a cooling drum while simultaneously forming a thin film on the web by vapor-phase deposition. A roll with a rebound hardness of no greater than 691L is used as the roll and a thin-film forming surface of a part of the web in contact with the cooling drum is irradiated with an electron beam.

### BACKGROUND OF THE INVENTION

1. Field of the Invention

The present invention relates to a thin-film forming method and a thin-film forming apparatus that form a thin film on a web by vapor-phase deposition, and to a magnetic recording medium manufacturing method that manufactures a magnetic recording medium by forming a thin metal film as a thin film according to the thin-film forming method.

2. Description of the Related Art

A method of manufacturing a deposited magnetic recording medium used for high-density recording (hereinafter simply “magnetic recording medium”) by forming a thin ferromagnetic metal layer (hereinafter simply “magnetic layer”) on a thermoplastic resin film (hereinafter simply “resin film”) according to this type of thin-film forming method is disclosed by Japanese Laid-Open Patent Publication No. 2000-16644. According to this method of manufacturing a magnetic recording medium, the magnetic layer is formed by running a resin film that has been wound into a roll (a “film roll”: hereinafter also referred to simply as the “roll”) inside a vacuum evaporation apparatus, for example, and depositing a magnetic layer forming material on a surface (the “magnetic layer forming surface”) of the resin film. During the evaporation process that deposits the magnetic layer forming material on the resin film, there is the risk of thermal deformation and the like occurring for the resin film that is exposed to high temperature. Accordingly, in this type of manufacturing method, to avoid an excessive rise in the temperature of the resin film, the resin film is normally run with the rear surface of the resin film (i.e., the rear surface with respect to the magnetic layer forming surface mentioned above) in contact with a cooling drum (i.e., the resin film is run around the cooling drum) and the magnetic layer forming material is deposited while the resin layer is being cooled.

When the resin film is wound into a roll before the magnetic layer is formed, if the resin film is wound too loosely, air becomes trapped between windings of the resin film. If the roll is used in a state where a large amount of air is trapped between the windings of the film, when the vacuum evaporation apparatus is evacuated during the formation of the magnetic layer (i.e., during the evaporation process), the large amount of air between windings of the resin film is expelled, thereby tightening the resin film in the rolled state and producing creases in the resin film (i.e., the resin film becomes buckled). Accordingly, with this method of manufacturing, by winding the resin film fairly firmly when forming the roll, it is possible to avoid having air trapped between windings of the resin film and therefore the production of creases during evacuation can be avoided. More specifically, a roll that has been firmly wound so that the hardness measured using an ASKER rubber hardness tester made by Koubunshi Keiki Co., Ltd. is in a range of 90° to 98°, inclusive is used.

### SUMMARY OF THE INVENTION

However, by investigating the conventional method of manufacturing described above, the present inventors found the following problem. With the conventional method of manufacturing, a firmly wound roll is used when forming the magnetic layer (i.e., during the evaporation process). To improve the running characteristics of the tape, extremely small concaves and convexes are sometimes formed on the rear surface (i.e., the rear surface with respect to the magnetic layer forming surface) of a resin film used to manufacture a magnetic tape or the like. When this type of resin film is firmly (i.e., tightly) wound, the magnetic layer forming surface is strongly pressed onto the rear surface of the resin film, which can cause the concaves and convexes of the rear surface to be transferred, thereby producing concaves and convexes in the magnetic layer forming surface of the resin film. When a magnetic layer is formed on a resin film in which concaves and convexes have been produced, concaves and convexes are also produced in the surface (i.e., the data recording surface) of the magnetic layer. Although such concaves and convexes in the magnetic layer do not cause a major problem in a recording/reproducing apparatus that uses an inductive head as the reproducing head, the present inventors found that when an MR (magnetoresistive effect element) head is used as the reproducing head, there is an increase in the number of errors due to noise caused by the concaves and convexes. This means that with the conventional method of manufacturing, there is the problem that noise is produced by the concaves and convexes produced in the data recording surface of the magnetic tape, which makes it difficult to properly record and reproduce data onto and from the magnetic tape.

On the other hand, if a loosely wound roll is used when forming the magnetic layer to avoid having concaves and convexes produced in the resin layer due to the resin film being tightly wound, as described earlier, creases can be produced in the resin film due to the air trapped between windings of the resin film being expelled in the vacuum. There are also cases where creases are produced in the resin film due to the presence of air trapped between windings of the resin film when the resin film is wound (i.e., loosely wound) even before evacuation in the vacuum evaporation apparatus. Since such creases cause deterioration in the contact between the resin film and the cooling drum, it becomes difficult to sufficiently cool the resin film, resulting in the risk of thermal deformation or the production of holes (i.e., holes that pass through from the rear surface to the recording surface of the resin film). There is also the risk of adsorbed moisture that remains on the resin film suddenly expanding between the resin film and the cooling drum due to the heat used during evaporation, thereby causing deterioration in the contact between the resin film and the cooling drum and leading to the risk of thermal deformation or the production of holes. If the resin film has been loosely wound into a roll where a large amount of air is trapped between the windings of the film, when air is evacuated in a vacuum evaporation apparatus during the formation of a magnetic layer (i.e., during the evaporation process), staggering can occur for the rolled resin film due to the large amount of air being expelled from between the windings of the resin film (i.e., the resin film can become disorderly wound on the roll). If the resin film is run out from a roll in this state (i.e., where staggering has occurred), the ends of the resin film in the width direction will be damaged, leading to the risk of the resin film breaking, which would result in significant deterioration in the mass-producibility of the magnetic recording medium.

The present invention was conceived in view of the problems described above and it is a principal object of the present invention to provide a thin-film forming method and a thin-film forming apparatus that while avoiding the production of concaves and convexes in a web, can avoid thermal deformation and the production of holes in the web during the formation of a thin film and to also provide a magnetic recording medium manufacturing method that can sufficiently reduce the noise level. It is a further object to provide a thin-film forming method and a thin-film forming apparatus that can avoid damage to ends of the web in the width direction during running.

To achieve the stated object, a thin-film forming method according to the present invention comprises feeding out a generally belt-shaped web from a roll produced by winding the web and causing the web to run around a cooling drum while simultaneously forming a thin film on the web by vapor-phase deposition, wherein a roll with a rebound hardness of no greater than 691 L is used as the roll and a thin-film forming surface of a part of the web in contact with the cooling drum is irradiated with an electron beam. Note that the expression “web” for the present invention includes various types of substrate in a state where a predetermined thin film has been formed on a film formed from a resin material, for example. The expression “vapor-phase deposition” for the present invention includes various deposition methods such as physical vapor deposition (PVD) (for example, sputtering or vacuum evaporation), and chemical vapor deposition (CVD). In addition, the expression “rebound hardness” for the present invention refers to an “L value” for the hardness measured using a “PAROtester 2” rebound-type hardness tester made by PROCEQ for a roll produced by winding the web around a core with a diameter of six inches (a roll produced by winding the web so that the distance from the circumferential surface of the core to the surface of the roll is 70 mm).

With the thin-film forming method according to the present invention and the thin-film forming apparatus described later, when forming a thin film on a web by vapor-phase deposition, by using a roll with a rebound hardness of no greater than 691 L and irradiating the thin-film forming surface at a part of the web in contact with the cooling drum with an electron beam, unlike the conventional method of manufacturing that uses a tightly wound roll, it is possible to avoid the production of concaves and convexes in the web due to the roll being tightly wound. Accordingly, it is possible to make the surface of the thin film formed on the web sufficiently smooth. By doing so, when manufacturing a magnetic recording medium, for example, in accordance with this thin-film forming method, it is possible to avoid having noise produced due to concaves and convexes produced in the surface of the magnetic recording medium. In addition, by charging the web by irradiating the web with the electron beam, it is possible to have the web adhere sufficiently tightly to the cooling drum so that the web is cooled reliably. By doing so, even though the roll is loosely wound to avoid producing concaves and convexes, it is still possible to avoid thermal deformation of the web and the production of holes during the process that forms the thin film.

In the thin-film forming method according to the present invention, a roll with a rebound hardness of no less than 374 L may be used as the roll. By doing so, it is possible to avoid having a large amount of air trapped between windings of the web on the roll, and as a result it is possible to avoid a situation where staggering occurs for the roll due to the air trapped between the windings of the web being expelled when a vacuum chamber is evacuated during the formation of the thin film. Accordingly, it is possible to avoid damage to the ends of the web in the width direction when the tape is run.

A magnetic recording medium manufacturing method according to the present invention manufactures a magnetic recording medium by forming a thin metal film as the thin film on the web in accordance with either of the thin-film forming methods described above. By manufacturing a magnetic recording medium in this way, it is possible to avoid the production of concaves and convexes in the web. As a result, it is possible to avoid having concaves and convexes produced in the surface of the magnetic recording medium, which makes it possible to manufacture a magnetic recording medium where the production of a large amount of noise due to such concaves and convexes is avoided and where data can be properly recorded and reproduced. Since it is possible to sufficiently avoid the production of defective products due to thermal deformation and the production of holes in the web, it is possible to sufficiently improve the yield for the magnetic recording medium.

A thin-film forming apparatus according to the present invention can form a thin film on a web and includes: a web running mechanism that feeds out a generally belt-shaped web from a roll produced by winding the web so that a rebound hardness of the roll is no greater than 691 L and causes the web to run; a cooling drum that cools the web that has been fed out; a thin-film forming unit that forms a thin film by vapor-phase deposition on the web running around the cooling drum; and an electron beam irradiating unit that irradiates a thin-film forming surface of a part of the web that contacts the cooling drum with an electron beam.

It should be noted that the disclosure of the present invention relates to a content of Japanese Patent Application 2005-291163 that was filed on 4 Oct. 2005 and the entire content of which is herein incorporated by reference.

### BRIEF DESCRIPTION OF THE DRAWINGS

These and other objects and features of the present invention will be explained in more detail below with reference to the attached drawings, wherein:

FIG. 1 is a block diagram showing the construction of a magnetic recording medium manufacturing system;

FIG. 2 is a cross-sectional view showing one example of the multilayer structure of a magnetic tape;

FIG. 3 is a diagram showing the construction of a magnetic layer forming apparatus;

FIG. 4 is a table useful in explaining the conditions for manufacturing magnetic tapes for examples and comparative examples; and

FIG. 5 is a table useful in explaining the relationship between rebound hardness (an L value) of a feeder roll and the occurrence of staggering, the production of holes, and the electromagnetic conversion characteristics for manufacturing magnetic tapes of examples and comparative examples.

### DESCRIPTION OF THE PREFERRED EMBODIMENTS

Preferred embodiments of a thin-film forming method, a magnetic recording medium manufacturing method, and a thin-film forming apparatus according to the present invention will now be described with reference to the attached drawings.

First, the construction of a magnetic recording medium manufacturing system 1 that manufactures a magnetic tape 10 in accordance with the magnetic recording medium manufacturing method according to the present invention and the construction of the magnetic tape 10 will be described with reference to the drawings.

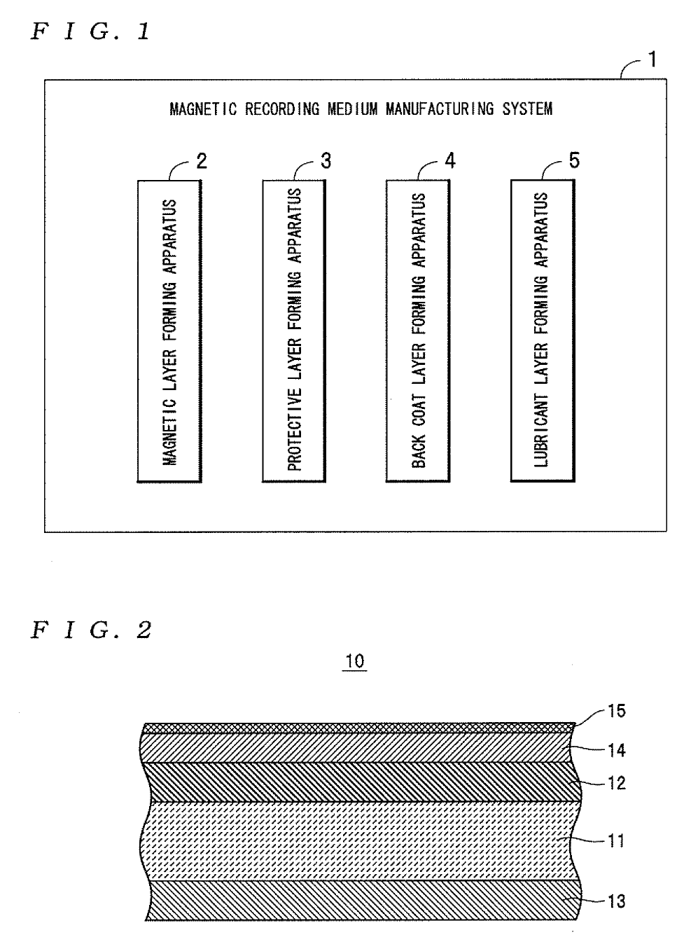

As one example, the magnetic recording medium manufacturing system 1 (hereinafter simply “manufacturing system 1”) shown in FIG. 1 includes a magnetic layer forming apparatus 2, a protective layer forming apparatus 3, a back coat layer forming apparatus 4, and a lubricant layer forming apparatus 5, and is constructed so as to be capable of manufacturing the magnetic tape 10 shown in FIG. 2. The magnetic tape 10 is one example of a “magnetic recording medium” for the present invention, and is constructed by forming a magnetic layer 12, a protective layer 14, and a lubricant layer 15 in the mentioned order on one surface (the upper surface in FIG. 2) of a base film 11. A back coat layer 13 is formed on the other surface (the lower surface in FIG. 2) of the base film 11.

The base film (non-magnetic substrate) 11 corresponds to a “web” for the present invention and is formed in a long belt-like shape from a film that can withstand high temperature during the process that forms the magnetic layer 12 (i.e., during the evaporation process described later) and has a thickness in a range of 3 μm to 10 μm, inclusive (as one example, 4.7 μm). There are no particular limitations on the material used as the base film 11, and as examples the base film 11 can be formed using polyethylene terephthalate (PET), polyethylene naphthalate (PEN)), polyamide, polyamide-imide, or polyimide. The base film 11 used when manufacturing the magnetic tape 10 or the like may be a single-layer film or a multilayer film. When using a multilayer film where fine particles (filler) are included in a layer on whose surface the back coat layer 13 will be formed, if the base film 11 is tightly wound into a roll, concaves and convexes can easily be produced on the surface on which the magnetic layer 12 will be formed, making it especially preferable to use the present invention as described later.

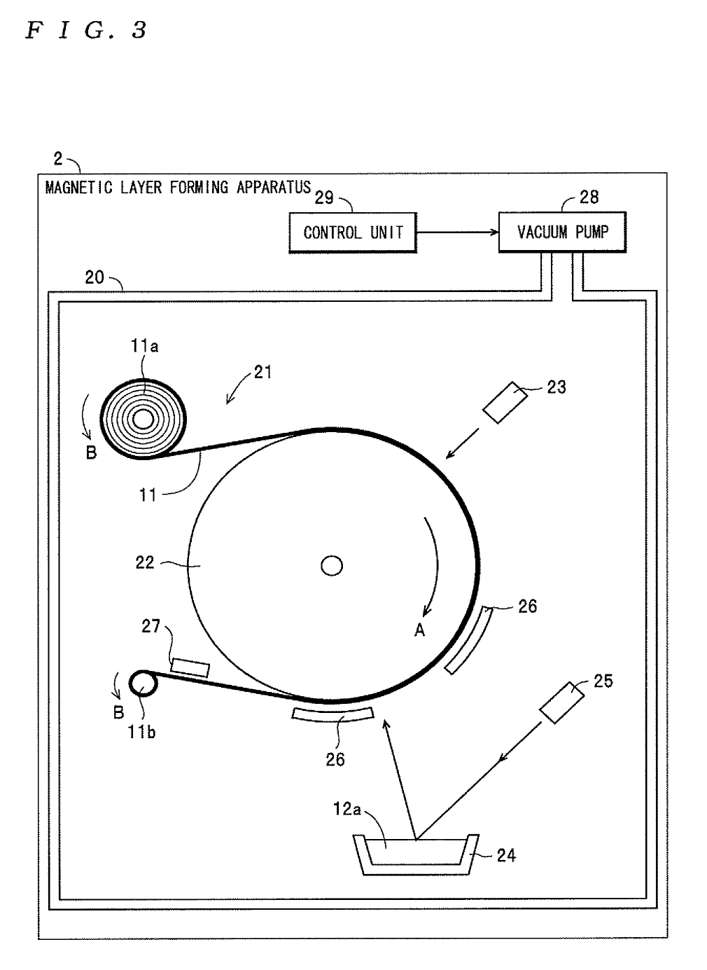

The magnetic layer 12 is one example of a “thin film” and a “thin metal film” formed in accordance with the thin-film forming method according to the present invention and is formed with a thickness in a range of 30 nm to 200 nm inclusive by forming a thin film of a magnetic material 12a (see FIG. 3) by vapor-phase deposition. A pure metal such as Co or Fe, or an alloy such as Co—Ni, Co—Fe, Co—Ni—Fe, Co—Cr, Co—Cu, Co—Ni—Cr, Co—Pt, Co—Pt—Cr, Co—Cr—Ta, Co—Ni—B, Co—Ni—Fe, Co—Fe—B, or Co—Ni—Fe—B can be used as the magnetic material 12a. Out of such materials, Co or a Co alloy should preferably be used due to their favorable electromagnetic conversion characteristics. It is also possible to use a variety of deposition methods as the vapor-phase deposition mentioned above, such as PVD (for example, sputtering or vacuum evaporation), and CVD.

The back coat layer 13 is a layer mainly for improving the tape running characteristics of the magnetic tape 10 and is formed with a thickness in a range of 0.1 μm to 0.7 μm inclusive by applying a back coat layer coating composition, where a binder resin and an inorganic compound and/or carbon black have been mixed in an organic solvent and dispersed, and then drying the applied coating composition. The protective layer 14 is a hard film for preventing deterioration in the magnetic layer 12, and as one example is formed by CVD using a material that has carbon as a main constituent and includes hydrogen. The lubricant layer 15 is mainly for improving the tape running characteristics of the magnetic tape 10 and is formed with a thickness of several nm or thereabouts by applying a lubricant that has been dissolved in a solvent and then drying the applied lubricant. As examples of the lubricant, it is possible to use a lubricant that includes fluororesin, a hydrocarbon ester, or a mixture of the same.

On the other hand, the magnetic layer forming apparatus 2 corresponds to the “thin-film forming apparatus” according to the present invention and forms the magnetic layer 12 on the base film 11 in accordance with the thin-film forming method according to the present invention. As shown in FIG. 3, the magnetic layer forming apparatus 2 includes a running mechanism 21, a cooling drum 22, an electron generating device 23, a crucible 24, an evaporation electron gun 25, shield plates 26, and a charge removing device 27 that are housed inside an evaporation chamber 20, and also includes a vacuum pump 28 for evacuating the internal space of the evaporation chamber 20 and a control unit 29 for carrying out overall control over the various components of the magnetic layer forming apparatus 2. The vacuum pump 28 expels air from inside the evaporation chamber 20 in accordance with control by the control unit 29 to keep the pressure inside the evaporation chamber 20 in a range of 10⁻³ Pa to 10^{31 4} Pa. Note that in FIG. 3, for ease of understanding the present invention, various tape rollers, tensioning mechanisms, and the like that are present between a feeder roll 11a and the cooling drum 22 and between the cooling drum 22 and a take-up roll 11b have been omitted from the drawings.

The running mechanism 21 corresponds to a “web running mechanism” for the present invention, includes a motor, not shown, and rotates the feeder roll 11a and the take-up roll 11b in accordance with control by the control unit 29 to cause the base film 11 fed out from the feeder roll 11a to run around the cooling drum 22 in the evaporation chamber 20. The feeder roll 11a corresponds to a “roll” for the present invention, and is formed by winding the base film 11 so that the rebound hardness is in a range of 374 L to 691 L, inclusive (as one example, 691 L). Note that the feeder roll 11a whose rebound hardness as measured by a “PAROtester 2” rebound-type hardness tester made by PROCEQ is 691 L has a hardness of 88° when measured using an ASKER rubber hardness tester made by Koubunshi Keiki Co., Ltd. That is, when manufacturing the magnetic tape 10 with the manufacturing system 1, a feeder roll 11a that is more loosely wound than a roll used in the conventional manufacturing method is used. The relationship between the rebound hardness of the feeder roll 11a and the electromagnetic conversion characteristics and conditions for forming a feeder roll 11a with a certain rebound hardness are described in detail later. The cooling drum 22 is rotated in the direction of the arrow A in FIG. 3 by the running mechanism 21 and cools the base film 11 due to the base film 11 fed out from the feeder roll 11a making tight contact with the circumferential surface of the cooling drum 22.

The electron generating device 23 corresponds to an “electron beam irradiating unit” for the present invention and charges the base film 11 by irradiating the base film 11 with an electron beam in accordance with control by the control unit 29. When doing so, to avoid thermal deformation of the base film 11 due to heat generated when the base film 11 is irradiated with the electron beam, the electron generating device 23 irradiates the surface of a part of the base film 11 that is in contact with the circumferential surface of the cooling drum 22 with the electron beam. As a result, the base film 11 becomes charged without the temperature rising excessively and therefore tightly adheres to the circumferential surface of the cooling drum 22. As one example, the electron generating device 23 scans the base film 11 in the width direction with the electron beam so that the entire base film 11 run by the running mechanism 21 is irradiated with the electron beam.

The crucible 24 holds a magnetic material 12a (metal to be evaporated) for forming the magnetic layer 12. The evaporation electron gun 25 irradiates the surface of the magnetic material 12a inside the crucible 24 with an electron beam to vaporize the magnetic material 12a to obliquely deposit the magnetic material 12a on the surface of the base film 11 running around the circumferential surface of the cooling drum 22. The shield plates 26 form a mask for restricting the region where the magnetic material 12a is deposited on the base film 11 running around the circumferential surface of the cooling drum 22 and are formed from a metal such as stainless steel. By suitably adjusting the positions of the upstream shield plate 26 and the downstream shield plate 26 in the running direction of the base film 11 and the gap between the shield plates 26, the magnetic material 12a is deposited at a desired angle onto the base film 11. The charge removing device 27 removes charge from the base film 11 which has been charged due to irradiation with the electron beam by the electron generating device 23 and on which the formation of the magnetic layer 12 has been completed. Note that the crucible 24, the evaporation electron gun 25, the shield plates 26, and the control unit 29 form a “thin-film forming unit” for the present invention.

The protective layer forming apparatus 3 forms the protective layer 14 by forming a hard film of a protective layer forming material (a material that has carbon as the main constituent and includes hydrogen) on the magnetic layer 12 by plasma CVD, for example. The back coat layer forming apparatus 4 applies a back coat layer coating composition onto the running surface (i.e., the lower surface shown in FIG. 2) of the base film 11 and then dries the back coat layer coating composition to form the back coat layer 13. Here, the back coat layer forming apparatus 4 applies the back coat layer coating composition using a die nozzle so that the thickness after drying of the back coat coating composition is 0.4 μm, for example. The lubricant layer forming apparatus 5 applies a lubricant that is dissolved in solvent onto the surface of the protective layer 14 and dries the lubricant to form the lubricant layer 15.

Next, the method of manufacturing the magnetic tape 10 using the manufacturing system 1 will be described with reference to the drawings.

First, as shown in FIG. 3, the feeder roll 11a is set inside the evaporation chamber 20 (i.e., in the running mechanism 21) of the magnetic layer forming apparatus 2 and the end of the base film 11 is pulled out from the feeder roll 11a, pulled around the circumferential surface of the cooling drum 22, and attached to the take-up roll 11b. Here, unlike the conventional method of manufacturing that uses a roll that has been tightly rolled so that the hardness as measured by an ASKER rubber hardness tester is 90° or above, when manufacturing the magnetic tape 10 using the manufacturing system 1, a feeder roll 11a that has been wound suitably loosely (in this example, wound so that the rebound hardness is 691L) is used. Accordingly, the surface (the surface on which the magnetic layer 12 is formed: corresponding to a “thin-film forming surface” for the present invention) of the base film 11 can be kept smooth without concaves and convexes being produced. Next, the control unit 29 controls the vacuum pump 28 to expel the air from inside the evaporation chamber 20 and starts cooling the base film 11 using the cooling drum 22. When doing so, since the feeder roll 11a that has not been wound excessively loosely is used, a situation is avoided where a large amount of air is expelled from between windings of the base film 11 on the feeder roll 11a during evacuation by the vacuum pump 28, which would result in staggering of the feeder roll 11a.

Next, the control unit 29 controls the running mechanism 21 to rotate the feeder roll 11a and the take-up roll 11b in the direction of the arrows B and to also rotate the cooling drum 22 in the direction of the arrow A. By doing so, the base film 11 is successively fed out from the feeder roll 11a and run around the circumferential surface of the cooling drum 22 toward the take-up roll 11b. When doing so, since a feeder roll 11a for which staggering does not occur is used, damage to the ends of the base film 11 in the width direction during running is avoided. Next, the control unit 29 controls the electron generating device 23 to start irradiating the base film 11 with the electron beam. When doing so, the base film 11 is charged by the irradiation with the electron beam and tightly adheres to the circumferential surface of the cooling drum 22. Accordingly, even if gentle creases are produced in the base film 11 due to the feeder roll 11a being loosely wound, tight contact between the base film 11 and the cooling drum 22 can be reliably achieved. As a result, the base film 11 is reliably cooled by the cooling drum 22. Here, in the magnetic layer forming apparatus 2, the electron generating device 23 irradiates the part of the base film 11 that tightly contacts the circumferential surface of the cooling drum 22 with the electron beam. Accordingly, an excessive rise in the temperature of the base film 11 during irradiation with the electron beam is avoided, thereby avoiding thermal deformation and the production of holes in the base film 11.

Next, the control unit 29 controls the evaporation electron gun 25 to start irradiating the magnetic material 12a inside the crucible 24 with the electron beam. When doing so, the magnetic material 12a inside the crucible 24 is vaporized due to the irradiation with the electron beam, passes between the shield plates 26, and is deposited on the surface of the base film 11 that is running around the circumferential surface of the cooling drum 22. In the magnetic layer forming apparatus 2, to achieve desired magnetic characteristics for the magnetic layer 12 that is formed, an oxidizing gas that may be any of oxygen, ozone, and nitrous oxide is introduced in a vicinity of material out of the magnetic material 12a (the deposited particles) that reaches the base (i.e., onto the base film 11 and the periphery thereof). By doing so, the magnetic layer 12 that is a thin film of the magnetic material 12a is formed on the surface of the base film 11. When doing so, since using the feeder roll 11a that has been wound suitably loosely makes it possible to avoid a situation where concaves and convexes are produced in the base film 11, the magnetic layer 12 formed on the base film 11 is formed with a smooth surface. In the magnetic layer forming apparatus 2, the magnetic material 12a is deposited on the base film 11 at a part of the base film 11 that tightly adheres to the circumferential surface of the cooling drum 22. Accordingly, it is possible to avoid an excessive rise in the temperature of the base film 11 while the magnetic material 12a is accumulating, so that thermal deformation of the base film 11 can be avoided.

On the other hand, the base film 11 on which the formation of the magnetic layer 12 has been completed has the charge removed therefrom by the charge removing device 27 and is then wound onto the take-up roll 11b. After this, when all of the base film 11 in the feeder roll 11a has been fed out and wound onto the take-up roll 11b, the process forming the magnetic layer 12 (the evaporation process) is complete. After this, the take-up roll 11b for which the formation of the magnetic layer 12 has been completed is taken out of the evaporation chamber 20 and set in the protective layer forming apparatus 3. When doing so, the protective layer forming apparatus 3 forms the protective layer 14 by forming a hard film of the protective layer forming material (a material that has carbon as a main constituent and includes hydrogen) by plasma CVD on the magnetic layer 12. After this, the back coat layer forming apparatus 4 has the base film 11 run by a running mechanism, not shown, while applying a coating composition for forming the back coat layer on the rear surface (i.e., an opposite surface to the formation surface of the magnetic layer 12) and dries the coating composition. By doing so, the formation of the back coat layer 13 is completed. Next, the lubricant layer forming apparatus 5 applies a lubricant that is dissolved in solvent onto the surface of the protective layer 14 and dries the lubricant to form the lubricant layer 15. By doing so, as shown in FIG. 2, the magnetic tape 10 is completed.

In this way, according to the method of forming the magnetic layer 12 using the magnetic recording medium manufacturing system 1 (i.e., the magnetic layer forming apparatus 2), when the magnetic layer 12 is formed on the base film 11 by vapor-phase deposition (in this example, vacuum evaporation), by using the feeder roll 11a that has a rebound hardness of no greater than 691 L (in this example, 691L) as the roll for the present invention and irradiating the surface (i.e., the thin-film forming surface) of a part of the base film 11 that contacts the cooling drum 22 with the electron beam, unlike the conventional method of manufacturing that uses a tightly wound roll, it is possible to avoid a situation where concaves and convexes are produced on the base film 11 due to the base film 11 being tightly wound. Since it is possible to make the surface of the magnetic layer 12 formed on the base film 11 sufficiently smooth, it is possible to make the surfaces of the protective layer 14 and the lubricant layer 15 formed on the magnetic layer 12 smooth, and therefore it is possible to avoid the production of noise due to the presence of concaves and convexes in the surface of the magnetic tape 10. Also, by charging the base film 11 by irradiating the base film 11 with an electron beam, it is possible to make the base film 11 adhere to the circumferential surface of the cooling drum 22 sufficiently tightly and thereby cool the base film 11 reliably. By doing so, in spite of the base film 11 being wound loosely to avoid the production of concaves and convexes, it is possible to avoid thermal deformation and the production of holes in the base film 11 during the formation of the magnetic layer 12.

Also, according to the method of forming the magnetic layer 12 using the magnetic recording medium manufacturing system 1 (i.e., the magnetic layer forming apparatus 2), by using a feeder roll 11a that has a rebound hardness of no less than 374 L (in this example, 691 L) as the roll for the present invention, it is possible to avoid a situation where a large amount of air is trapped between windings of the base film 11 on the feeder roll 11a. As a result, it is possible to avoid a situation where staggering occurs for the feeder roll 11a when air trapped between windings of the base film 11 is expelled during the evacuation of the evaporation chamber 20. Accordingly, it is possible to avoid damage to the ends of the base film 11 in the width direction during running of the tape.

According to the method of forming the magnetic tape 10 using the magnetic recording medium manufacturing system 1, by manufacturing the magnetic tape 10 by forming the magnetic layer 12 (a thin metal film) on the base film 11 in accordance with the thin-film forming method according to the present invention, it is possible to avoid a situation where concaves and convexes are produced on the base film 11. As a result, since it is possible to avoid having concaves and convexes produced on the surface of the magnetic tape 10, it is possible to manufacture a magnetic tape 10 onto and from which data can be properly recorded and reproduced while avoiding the production of a large amount of noise due to concaves and convexes. Since it is possible to avoid the production of defective products due to thermal deformation or holes in the base film 11, the yield of the magnetic tape 10 can be sufficiently improved.

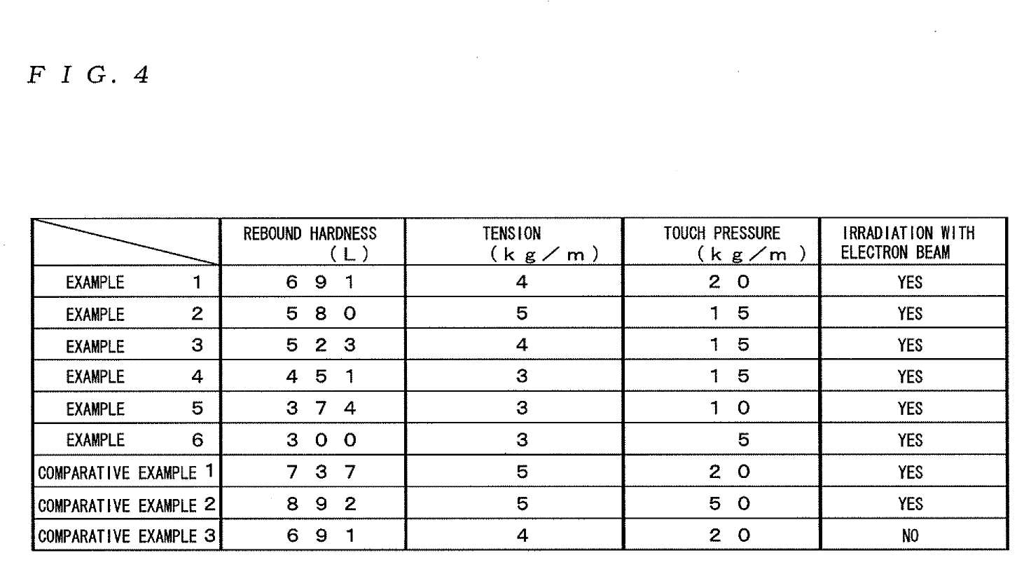

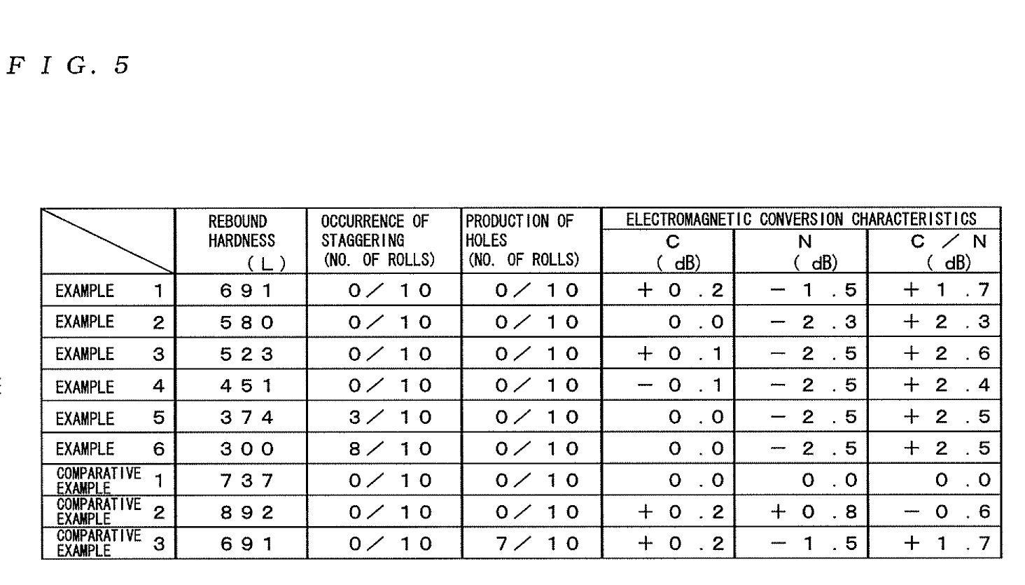

Next, interrelationships between the rebound hardness of the feeder roll 11a, the production of holes in the base film 11, the electromagnetic conversion characteristics, and the occurrence of staggering for the feeder roll 11a will be described with reference to FIGS. 4 and 5.

Ten rolls of magnetic tape (i.e., the base film used to manufacture a magnetic tape) were manufactured for each of examples 1 to 6 and comparative examples 1 to 3 using the manufacturing system 1 described above, and the presence of staggering inside the evaporation chamber 20, the number of rolls where holes were produced in the base film 11 during the process that forms the magnetic layer 12, and the electromagnetic conversion characteristics were investigated. When doing so, as the rebound hardness of the feeder roll 11a for the examples and the comparative examples, the hardness was measured at ten points in the width direction of the feeder roll 11a in a state where the base film 11 has been wound with a thickness of 70 mm around a core with a diameter of six inches and an average of the ten measurements was set as the rebound hardness of the feeder roll 11a. Also, when measuring the electromagnetic conversion characteristics, recording and reproducing were carried out using a drum tester with the conditions given below.

Recording: recording with a wavelength of 0.5 μm using an MIG head with a gap length of 0.22 μm

Reproducing: Reproducing using an AMR head

Detection of noise: Measured using a frequency corresponding to a wavelength of 0.6 μm

Note that “C(dB)”, “N(dB)”, and “C/N(dB)” in the electromagnetic conversion characteristics shown in FIG. 5 are given as values expressed relative to the measurement values for the magnetic tapes of comparative example 1.

### EXAMPLE 1

A base film 11 made of polyethylene naphthalate (PEN) with a thickness of 4.7 μm and a length of 10,000 m was wound to form the feeder roll 11a. When doing so, by setting the tension of the winding apparatus (not shown) at 4 kg/m and the touch pressure of the touch roll at 20 kg/m, the base film 11 was wound so that the rebound hardness of the feeder roll 11a was 691 L (see FIG. 4). Also, by using Co as the magnetic material 12a and carrying out the evaporation process while introducing oxygen as the oxidizing gas, the magnetic layer 12 was formed with a thickness of 140 nm. The methods of forming the magnetic layer 12, the back coat layer 13, the protective layer 14, and the lubricant layer 15 and the order in which such layers were formed were the same as the methods and the order used when manufacturing the magnetic tape 10 described above.

### EXAMPLE 2

When forming the feeder roll 11a, by setting the tension of the winding apparatus (not shown) at 5 kg/m and the touch pressure of the touch roll at 15 kg/m, the base film 11 was wound so that the rebound hardness of the feeder roll 11a was 580 L (see FIG. 4). The other conditions were the same as example 1.

### EXAMPLE 3

When forming the feeder roll 11a, by setting the tension of the winding apparatus (not shown) at 4 kg/m and the touch pressure of the touch roll at 15 kg/m, the base film 11 was wound so that the rebound hardness of the feeder roll 11a was 523 L (see FIG. 4). The other conditions were the same as example 1.

### EXAMPLE 4

When forming the feeder roll 11a, by setting the tension of the winding apparatus (not shown) at 3 kg/m and the touch pressure of the touch roll at 15 kg/m, the base film 11 was wound so that the rebound hardness of the feeder roll 11a was 451 L (see FIG. 4). The other conditions were the same as example 1.

### EXAMPLE 5

When forming the feeder roll 11a, by setting the tension of the winding apparatus (not shown) at 3 kg/m and the touch pressure of the touch roll at 10 kg/m, the base film 11 was wound so that the rebound hardness of the feeder roll 11a was 374 L (see FIG. 4). The other conditions were the same as example 1.

### EXAMPLE 6

forming the feeder roll 11a, by setting the tension of the winding apparatus (not shown) at 3 kg/m and the touch pressure of the touch roll at 5 kg/m, the base film 11 was wound so that the rebound hardness of the feeder roll 11a was 300 L (see FIG. 4). The other conditions were the same as example 1.

### COMPARATIVE EXAMPLE 1

When forming the feeder roll 11a, by setting the tension of the winding apparatus (not shown) at 5 kg/m and the touch pressure of the touch roll at 20 kg/m, the base film 11 was wound so that the rebound hardness of the feeder roll 11a was 737 L (see FIG. 4). The other conditions were the same as example 1.

### COMPARATIVE EXAMPLE 2

When forming the feeder roll 11a, by setting the tension of the winding apparatus (not shown) at 5 kg/m and the touch pressure of the touch roll at 50 kg/m, the base film 11 was wound so that the rebound hardness of the feeder roll 11a was 892 L (see FIG. 4). The other conditions were the same as example 1.

### COMPARATIVE EXAMPLE 3

Comparative example 3 was manufactured with the same conditions as example 1, except that the base film 11 was not irradiated with an electron beam by the electron generating device 23.

As shown in FIG. 5, there was deterioration in the noise level for the magnetic tapes of comparative example 1 manufactured using the feeder roll 11a with the rebound hardness of 737 L. Greater deterioration in the noise level was observed for the magnetic tapes of comparative example 2 manufactured using the feeder roll 11a with the rebound hardness of 892 L compared to the magnetic tapes of the comparative example 1. On the other hand, for the magnetic tapes of examples 1 to 6 and comparative example 3 manufactured using feeder rolls 11a with a rebound hardness of no greater than 691 L, the noise level was sufficiently lower than for the magnetic tapes of comparative example 1. Accordingly, by winding the base film 11 so that the rebound hardness of the feeder roll 11a is no greater than 691 L, it is possible to sufficiently reduce the noise level of the magnetic tapes manufactured using the feeder roll 11a. Accordingly, it is possible to sufficiently reduce the occurrence of reproduction errors even for a recording/reproducing apparatus equipped with an MR head or the like where it is difficult to reproduce data properly when noise is present. Also, since the magnetic tapes of examples 1 to 6 have improved C/N ratios compared to comparative examples 1 and 2 due to the reduced noise level, it becomes possible to reproduce the data stably.

For the magnetic tapes of comparative example 3 where the base film 11 was not irradiated with the electron beam by the electron generating device 23 (i.e., the base film 11 was not charged), holes were produced in the base film 11 for seven out of the ten rolls. On the other hand, no holes were produced in any of the base films 11 of the magnetic tapes of examples 1 to 6 and comparative examples 1 and 2 where the base films 11 were irradiated by the electron generating device 23 with the electron beam (i.e., where the base film 11 was charged). Accordingly, by irradiating the base film 11 with the electron beam at the part where the base film 11 contacts the circumferential surface of the cooling drum 22, even when a roll that has been wound more loosely than a roll used in a conventional method of manufacturing is used, it is possible to cause the base film 11 to tightly adhere to the cooling drum 22 and thereby avoid the production of holes.

For the magnetic tapes of example 6 manufactured using the feeder roll 11a with a rebound hardness of below 374 L (i.e., using the feeder roll 11a with a rebound hardness of 300 L), when the evaporation chamber 20 was evacuated during the formation of the magnetic layer 12, although non-defective rolls were obtained for two out of the ten rolls, staggering of the feeder roll 11a occurred for the remaining eight rolls. On the other hand, for the magnetic tapes of example 5 manufactured using the feeder roll 11a with a rebound hardness of 374 L, although staggering of the feeder roll 11a occurred for three out of the ten rolls when the evaporation chamber 20 was evacuated, no staggering occurred for the remaining seven rolls. In addition, for the magnetic tapes of examples 1 to 4 and comparative examples 1 to 3 manufactured using feeder rolls 11a with a rebound hardness of no less than 451 L, no staggering occurred for any of the feeder rolls 11a. Accordingly, by winding the base film 11 so that the rebound hardness of the feeder roll 11a is no less than 374 L, it is possible to sufficiently avoid the occurrence of staggering during evacuation. Also, by winding the base film 11 so that the rebound hardness of the feeder roll 11a is no less than 451 L, it is possible to almost completely avoid the occurrence of staggering during evacuation.

From the above results, it is clear that to avoid staggering for the feeder roll 11a during evacuation, to avoid the occurrence of thermal deformation and the production of holes for the base film 11 during the process that forms the magnetic layer 12 (i.e., during the evaporation of the magnetic material), and to reduce the noise level of the manufactured magnetic tape, it is necessary to use a feeder roll 11a whose rebound hardness is in a range of 374 L to 691 L, inclusive, and to irradiate a part of the base film 11 in contact with the circumferential surface of the cooling drum 22 with an electron beam. By doing so, it is possible to manufacture a magnetic tape onto and from which data can be recorded and reproduced properly. Note that it was confirmed that “blocking” or “delamination”, where the coating layer applied to the surface of the base film 11 is transferred to the opposite surface of the base film 11 and the coating layer peels off when the base film 11 is fed out from the feeder roll 11a, which damages the base film 11, occurs with a feeder roll 11a with a rebound hardness of over 691 L. This means that when a feeder roll 11a with a rebound hardness of over 691 L is used, due to the great damage caused by blocking and delamination, large concaves and convexes are produced in the surface of the magnetic tape, resulting in spacing loss and the production of parts (i.e., defects) where the signal level of the carrier signal drops significantly, thereby reducing the yield of the magnetic tape. Accordingly, by using a feeder roll 11a with a rebound hardness of no greater than 691 L, it is possible to improve the yield of the magnetic tape and thereby to reduce the manufacturing cost of the magnetic tape.

Note that although an example where the magnetic layer 12 is formed by evaporation has been described, the vapor-phase deposition carried out by the thin-film forming method according to the present invention is not limited to evaporation and it is possible to use various types of vapor-phase deposition such as PVD aside from evaporation, or CVD. Also, although an example where the magnetic layer 12 is formed directly on the base film 11 has been described, it is also possible to form an underlayer (not shown) between the base film 11 and the magnetic layer 12 to improve the S/N characteristics or for other reasons. Such underlayer is one example of a so-called “non-magnetic layer” or a functional layer that is extremely close to a non-magnetic layer, and can be formed by the same method as the magnetic layer 12. More specifically, as one example, it is possible to form the underlayer by increasing the introduced amount of oxygen during the evaporation process compared to when the magnetic layer 12 is formed. Accordingly, by implementing the thin-film forming method according to the present invention when forming the underlayer, it is possible to avoid staggering for the feeder roll 11a during evacuation, to avoid the production of holes in the base film 11 during the process that forms the underlayer (i.e., during the evaporation of non-magnetic material), and to make the surface of the manufactured magnetic tape smooth, thereby reducing the noise level.

In addition, after the underlayer has been formed, by carrying out the thin-film forming method according to the present invention to form the magnetic layer 12 on the underlayer, it is possible to avoid staggering for the feeder roll 11a (i.e., a feeder roll 11a produced by winding the base film 11 in a state where the underlayer has been formed) during evacuation, to avoid the production of holes in the base film 11 during the process that forms the magnetic layer 12 (i.e., during the evaporation of magnetic material), and to make the surface of the manufactured magnetic tape smooth, thereby reducing the noise level. In addition, although an example where a magnetic layer 12 and an underlayer for forming a magnetic tape are formed in accordance with the thin-film forming method according to the present invention has been described, the thin films formed by the thin-film forming method according to the present invention are not limited to layers of a magnetic recording medium. For example, by implementing the thin-film forming method according to the present invention when forming deposited films used for decoration or packaging, thin films for electrodes of a capacitor, or the like, it is possible to avoid thermal deformation and the production of holes in a web while making the surface of the thin film smooth.

What is claimed is:

1. A thin-film forming method comprising:
feeding out a generally belt-shaped web from a roll produced by winding the web; and
causing the web to run around a cooling drum while simultaneously forming a thin film on the web by vapor-phase deposition,
wherein a roll with a rebound hardness of no greater than 691 L is used as the roll and a thin-film forming surface of a part of the web in contact with the cooling drum is irradiated with an electron beam.

2. A thin-film forming method according to claim 1, wherein a roll with a rebound hardness of no less than 374 L is used as the roll.

3. A magnetic recording medium manufacturing method that manufactures a magnetic recording medium by forming a thin metal film as the thin film on the web in accordance with a thin-film forming method according to claim 1.

4. A thin-film forming apparatus configured to form a thin film on a web, comprising:
a web running mechanism that feeds out a generally belt-shaped web from a roll produced by winding the web so that a rebound hardness of the roll is no greater than 691 L and causes the web to run;
a cooling drum that cools the web that has been fed out;
a thin-film forming unit that forms a thin film by vapor-phase deposition on the web running around the cooling drum; and
an electron beam irradiating unit that irradiates a thin-film forming surface of a part of the web that contacts the cooling drum with an electron beam.
